(19) United States
(12) Patent Application Publication
(10) Pub. No.: US 2015/0064471 A1
(43) Pub. Date: Mar. 5, 2015

(54) Seed for Metal Dichalcogenide Growth by Chemical Vapor Deposition

(71) Applicant: Massachusetts Institute of Technology, Cambridge, MA (US)

(72) Inventors: Mildred S. Dresselhaus, Arlington, MA (US); Jing Kong, Winchester, MA (US); Yi-Hsien Lee, Cambridge, MA (US); Xi Ling, Cambridge, MA (US)

(21) Appl. No.: 14/469,777

(22) Filed: Aug. 27, 2014

Related U.S. Application Data
(60) Provisional application No. 61/870,970, filed on Aug. 28, 2013.

(51) Int. Cl. C23C 16/30; C23C 14/24; C23C 14/18; C23C 14/06; C23C 14/16; C23C 16/56; C23C 14/14

(52) U.S. Cl. CPC C23C 16/305; C23C 16/56; C23C 14/24; C23C 14/14; C23C 14/0694; C23C 14/16; C23C 14/18
USPC 428/408; 156/246; 428/704; 428/457; 428/698; 428/523

(57) ABSTRACT

A metal dichalcogenide layer is produced on a transfer substrate by seeding F₁₆CuPc molecules on a surface of a growth substrate, growing a layer (e.g., a monolayer) of a metal dichalcogenide via chemical vapor deposition on the growth substrate surface seeded with F₁₆CuPc molecules, and contacting the F₁₆CuPc-molecule and metal-dichalcogenide coated growth substrate with a composition that releases the metal dichalcogenide from the growth substrate.

### RELATED APPLICATION

This application claims the benefit of U.S. Provisional Application No. 61/870,970, filed 28 Aug. 2013, the entire content of which is incorporated herein by reference.

### GOVERNMENT SUPPORT

This invention was made with Government support under Grant No. 1004147 and under Grant No 6918851, both awarded by the National Science Foundation. The Government has certain rights in this invention.

### BACKGROUND

Recently, monolayers of layered transition-metal dichalcogenides (LTMDs), such as MX₂ (where M=Mo or W and where X=S or Se), have been reported to exhibit significant spin-valley coupling and optoelectronic performances because of their unique structural symmetry and band structures. Monolayers in this class of materials offer advantages for burgeoning fields in fundamental physics, energy harvesting, electronics and optoelectronics. Most studies to date, however, are hindered by the great challenges of synthesizing and transferring high-quality layered transition-metal dichalcogenide monolayers. Hence, a feasible synthetic process to overcome these challenges would be advantageous.

Considerable efforts have been devoted to synthesize an MoS₂ monolayer, including various kinds of exfoliations, physical vapor deposition, and chemical vapor deposition (CVD). Recently, a CVD-MoS₂ monolayer was presented with sulfurization of the thin Mo layer and induced layer growth using fragments of reduced graphene oxide as seeds. Y. Zhan, et. al, “Large-area vapor-phase growth and characterization of MoS₂ atomic layers on a SiO₂ substrate,” Small, 8, 966-971 (2012). The as-grown layers, however, displayed obvious thickness variation; and their optoelectronic performance was a few orders of magnitude worse than that of exfoliated layers. Further applications and scientific study have been hindered due to reduced mobility and a low on-off current ratio because of the high defect concentration and small grain size. Accordingly, most studies still use exfoliated samples since the synthesis of high-quality layered transition-metal dichalcogenide monolayers has remained a great challenge thus far.

Previous patent applications directed to a method for the synthesis and transfer of transition metal disulfide layers on diverse surfaces include U.S. application Ser. No. 14/193,962 and PCT Patent Application No. US2014/019575, both filed on 28 Feb. 2014; the inventors named in those applications are likewise named as inventors of the inventions defined herein.

### SUMMARY

Methods for fabricating and transferring a metal dichalcogenide and related structures are described herein. Various exemplifications of the methods and structures may include some or all of the elements, features and steps, described below.

A metal dichalcogenide layer is produced on a transfer substrate by seeding copper(II) 1,2,3,4,8,9,10,11,15,16,17,18,22,23,24,25-hexadecafluoro-29H,31H-phthalocyanine (F₁₆CuPc) molecules on a surface of a growth substrate, growing a layer (e.g., a monolayer) of a metal dichalcogenide via chemical vapor deposition on the growth substrate surface seeded with F₁₆CuPc molecules, and contacting the F₁₆CuPc-molecule and metal-dichalcogenide coated growth substrate with a composition that releases the metal dichalcogenide from the growth substrate.

In various embodiments, a transfer medium is adhered to the metal dichalcogenide layer before the metal dichalcogenide is released, and the two layers are released together in their entirety (adhered to each other)—or leaving only trace residues. Additionally, after release, the metal dichalcogenide layer can be transferred to a target substrate with a simple stamping. Next, the transfer medium (e.g., PMMA) can be removed by immersing in an acetone solvent or annealing at a temperature of 350° C.

The metal dichalcogenide can have a composition represented by the formula, MX₂, where M includes a metal selected from molybdenum (Mo), tungsten (W), and other transition metals and where X is a chalcogen selected from sulfur (S), selenium (Se) and tellurium (Te). In one embodiment, X is sulfur and M is molybdenum; and the MoS₂ layer is grown at a temperature of about 650° C. In another embodiment, X is sulfur and M is tungsten; and the WS₂ layer is grown at a temperature of about 800° C.

In various embodiments, the chalcogen is evaporated into a vapor phase and carried with inner carrier gas (e.g., nitrogen or argon gas) flow in the chemical vapor deposition. The metal can be supplied as MO₃ in the chemical vapor deposition. Moreover, the chemical vapor deposition can be performed at ambient pressure.

In particular embodiments, use of F₁₆CuPc molecules as a seed enables the construction of the hybrid structures of MoS₂/Au, MoS₂/h-BN and MoS₂/graphene by directly growing MoS₂ on the top of Au, h-BN and graphene, which is advantageous for extending the applications of MoS₂ in the other fields. The F₁₆CuPc seed molecules can be uniformly deposited on diverse substrates by thermal evaporation (in contrast, the previous seeds were deposited via aqueous solution), thus facilitating the direct growth of MoS₂ on diverse hydrophobic substrates, such as gold, graphene and h-BN. This significantly enables the growth of hybrid structures among functional materials, transition-metal-dichalcogenide monolayers and graphene-like two-dimensional materials.

The as-grown metal dichalcogenide layer can be in the form of a monolayer. The solution for releasing the metal dichalcogenide can be an inorganic base solution including, e.g., potassium hydroxide (KOH) and/or sodium hydroxide (NaOH); and the transfer medium can be, e.g., polydimethylsiloxane (PDMS) or poly(methyl methacrylate) (PMMA). Meanwhile, the growth substrate can be formed of, e.g., silicon with a silica surface coating (SiO₂/Si;) and the target substrate can be formed of, e.g., quartz, sapphire or silica.

Additional embodiments demonstrate the growth of high-quality MS₂ monolayers (e.g., where M=Mo or W) using ambient-pressure chemical vapor deposition (APCVD) with the seeding of F₁₆CuPc on a growth substrate. The growth of a MS₂ monolayer can be achieved on various substrate surfaces with significant flexibility to surface corrugation; and the electronic transport and optical performances of the as-grown MS₂ monolayers are comparable to those of exfoliated MS₂ monolayers. Also demonstrated is a robust technique for transferring MS₂ monolayer samples to diverse surfaces, which may stimulate progress on this class of materials and open a new route toward the synthesis of various novel hybrid structures including layered transition-metal dichalcogenide monolayer and functional materials.

Advantages that can be offered by various embodiments include the following. First, numerous novel performance and unique optical properties can be observed in the layered transition-metal dichalcogenide monolayer. Second, these methods of fabrication enable direct growth of a layered transition-metal dichalcogenide monolayer on diverse surfaces or nanostructures. Third, these methods of fabrication are scalable and enable formation of a high-quality layered transition-metal dichalcogenide monolayer. Fourth, these methods of fabrication can be simple and low-cost. Fifth, these structures can be fabricated at low growth temperatures.

Exemplary applications for these monolayers (i.e., devices in which these monolayers can be included) include the following: flexible electronics and optoelectronics; hybrid heterostructures with two-dimensional materials; advanced semiconductor devices and integrated circuits; short-channel devices and electronic circuits requiring low stand-by power; novel physical phenomenon and spin-related devices; valleytronics devices; energy harvesting issues, such as water splitting and hydrogen production; batteries and supercapacitors.

### BRIEF DESCRIPTION OF THE DRAWINGS

FIG. 1 is a schematic diagram of an experimental setup for the synthesis of a MS₂ monolayer.

FIG. 2 provides an illustration of the chemical structure of PTAS (right) and a schematic picture for the growth process on diverse surfaces (left).

FIG. 3 plots the temperature dependence of the weight loss and differential weight loss of PTAS using thermogravimetry analysis (TGA).

FIG. 4 provides a scanning-electron-microscope (SEM) image of MoS₂ grown on the cleaved side-wall of a Si substrate.

FIG. 5 provides an SEM image of WS₂ grown on the cleaved side-wall of a Si substrate.

FIG. 6 provides an SEM image of monolayer MoS₂ on a 5 μm Si particle.

FIG. 7 provides an SEM image of monolayer MoS₂ on aggregates of TiO₂ nanoparticles.

FIG. 8 provides an SEM image of monolayer MoS₂ on sapphire.

FIG. 9 is an optical microscope (OM) image of monolayer MoS₂ on quartz.

FIG. 10 is an atomic-force-microscopy (AFM) image of the surface of a SiO₂/Si substrate prior to seed treatment.

FIG. 11 is an AFM image of the surface of the substrate of FIG. 10 after seed treatment and after the same heating procedures as used in the growth of MoS₂.

FIG. 12 is an AFM image of the surface of the substrate of FIG. 11 after a WS₂ monolayer is formed thereon.

FIG. 13 is an AFM image of the surface of the substrate of FIG. 12 after removal of the as-grown MoS₂ monolayer.

FIG. 14 plots nano-AES spectra for the as-grown MoS₂ on silicon particles and on an aggregation of TiO₂ nanoparticles.

FIG. 15 is an SEM image of the as-grown MoS₂ on a silicon particle.

FIG. 16 is an SEM image of the as-grown MoS₂ on an aggregation of TiO₂ nanoparticles.

FIG. 17 provides an optical-microscope (OM) image of MoS₂ monolayer near an edge region.

FIG. 18 provides an optical-microscope image of WS₂ monolayer near an edge region.

FIG. 19 provides an enlarged optical-microscope image of the marked area in FIG. 17, with the inset showing the corresponding AFM images.

FIG. 20 provides an enlarged optical-microscope image of the marked area in FIG. 18, with the inset showing the corresponding AFM images.

FIG. 21 provides a low-magnification TEM image of as-grown MoS₂, with the inset showing the corresponding selected-area-electron-diffraction pattern.

FIG. 22 provides a low-magnification TEM image of as-grown WS₂, with the inset showing the corresponding selected-area-electron-diffraction pattern.

FIG. 23 provides a high-resolution TEM image of as-grown MoS₂.

FIG. 24 provides a high-resolution TEM image of as-grown WS₂.

FIG. 25 is a low-magnification TEM image of a few-layer WS₂ flake, where the numbers mark regions with different thicknesses.

FIG. 26 are the corresponding selected-area-electron-diffraction patterns of the different regions shown in FIG. 6a.

FIG. 27 plots the TEM-EDX spectra of the as-grown MoS₂ and WS₂.

FIG. 28 plots the x-ray photoelectron spectra for the molybdenum (Mo) 3d orbit of the as-grown MoS₂.

FIG. 29 plots the x-ray photoelectron spectra for the sulfur (S) 2p orbits of the as-grown MoS₂.

FIG. 30 plots the x-ray photoelectron spectra for the tungsten (W) 4f orbits of the as-grown WS₂.

FIG. 31 plots the x-ray photoelectron spectra for the sulfur (S) 2p orbits of the as-grown WS₂.

FIG. 32 maps the Raman peak intensity of a MoS₂ monolayer.

FIG. 33 provides an optical-microscope image of the MoS₂ monolayer.

FIG. 34 provides the photoluminescence (PL) peak intensity of a MoS₂ monolayer.

FIG. 35 maps the Raman peak intensity of WS₂ flakes.

FIG. 36 provides an optical-microscope image of the WS₂ flakes.

FIG. 37 provides the photoluminescence peak intensity of the WS₂ flakes.

FIG. 38 provides a comparison of the MS₂ monolayer and bulk for Raman spectra.

FIG. 39 provides a comparison of the MS₂ monolayer and bulk for photoluminescence spectra.

FIG. 40 plots transport characteristics of field-effect transistors (FETs) fabricated on as-grown MoS₂ on a linear scale (right y-axis) and on a log scale (left y-axis).

FIG. 41 plots output characteristics of the MoS₂ FET, where the current is linear with the source drain voltage in the low electronic field region, indicating that the metal electrodes form ohmic contact with MoS₂.

FIG. 42 plots transport characteristics of the FET fabricated on an as-grown WS₂ monolayer on a linear scale (right y-axis) and a log scale (left y-axis).

FIG. 43 plots output characteristics of the WS₂ FET.

FIG. 44 includes a series of images (a-d) of an as-grown MoS₂ sample on a SiO₂/Si substrate contained in a bottle; in photographic image (1), the sample is shown on the substrate with a clean SiO₂/Si substrate on the right; in photographic image (b), the same sample is shown with the as-grown monolayer peeling off and breaking into small pieces in the de-ionized water; photographic image (c) shows the drying of a droplet of the MoS₂ nanosheets solution; image (d) is an enlarged optical microscope image of transferred MoS₂ nanosheets on the SiO₂/Si substrate.

FIG. 45 plots the Raman signal and photoluminescence spectrum of the transferred MoS₂ nanosheets from image (d) of FIG. 44.

FIG. 46 shows the photoluminescence spectra of transferred MoS₂ on polyethylene terephthalate and polydimethylsiloxane surfaces; the photoluminescence experiments were performed using a 532-nm excitation laser.

FIG. 47 shows an optical-microscope image of MoS₂ transferred on a CVD graphene surface.

FIG. 48 shows an optical-microscope image of MoS₂ transferred on CVD h-BN surfaces.

FIG. 49 shows MoS₂ on BiFeO₃, with an inset showing the SEM image of the clear interface between MoS₂ on BiFeO₃ and the BiFeO₃ substrate only.

FIG. 50 is a schematic illustration of a CVD system for depositing MoS₂.

FIG. 51 is a plot of a temperature programming process used for MoS₂ growth.

FIG. 52 plots the photoluminescence spectrum of MoS₂ grown samples prepared with PTAS seed (top plot) and without seed (lower plot), where the excitation wavelength is 532.5 nm.

FIG. 53 plots the Raman spectrum of MoS₂ grown samples prepared with PTAS seed (top plot) and without seed (lower plot), where the excitation wavelength is 532.5 nm.

FIG. 54 includes optical images of the surface after the MoS₂ growth using different aromatic molecules as seeds. The names and thicknesses of the seeds are labeled on the images. The insets show the corresponding molecular structures or AFM images of the surface after MoS₂ growth. The shaded bars to the right side of the AFM images are 10 nm for PTCDA, 20 nm for TCTA and Spiro-2-NPS, 30 nm for BCP, and 50 nm for Ir(ppy)₃.

FIG. 55 is a schematic illustration of a MoS₂/Au/SiO₂/Si hybrid structure.

FIG. 56 is an optical-microscope image of the MoS₂/Au/SiO₂/Si hybrid structure illustrated in FIG. 55; this structure was formed by using F₁₆CuPc as a seed.

FIG. 57 is a schematic illustration of a MoS₂/exfoliated h-BN/SiO₂/Si hybrid structure.

FIG. 58 is an optical-microscope image of the MoS₂/exfoliated h-BN/SiO₂/Si hybrid structure illustrated in FIG. 57; this structure was formed by using F₁₆CuPc as a seed.

FIG. 59 is a schematic illustration of a MoS₂/exfoliated graphene/SiO₂/Si hybrid structure.

FIG. 60 is an optical-microscope image of the MoS₂/exfoliated graphene/SiO₂/Si hybrid structure illustrated in FIG. 59; this structure was formed by using F₁₆CuPc as a seed.

FIG. 61 plots the photoluminescence spectra of MoS₂ formed on Au, h-BN and graphene (or graphite).

FIG. 62 plots the Raman spectra of MoS₂ formed on Au, h-BN and graphene (or graphite).

FIG. 63 plots the photoluminescence and Raman (inset) spectra of MoS₂ grown by different kinds of seeds (indicated in the upper left corner of the photoluminescence plots.

FIG. 64 includes (a) an optical-microscope image of a large-area continuous, uniform, and high-quality MoS₂ monolayer grown by using F₁₆CuPc as a seed; (b) an AFM image of a triangular MoS₂ monolayer grown by using F₁₆CuPc as a seed and (c) an AFM image of a continuous MoS₂ monolayer grown by using F₁₆CuPc as a seed.

FIG. 65 plots the Raman spectra of 2 Å F₁₆CuPc on graphene before (top line) and after (bottom line) annealing at 650° C. The excitation wavelength is 632.8 nm. The G and G′-band of graphene are shown on the spectra. The peaks from 1100 to 1550 cm⁻¹ are assigned to the Raman modes of F₁₆CuPc.

FIG. 66 shows optical-microscope images of MoS₂ growth (a) without using a seed on Au/SiO₂/Si, (b) without using a seed on exfoliated h-BN/SiO₂/Si, and (c) without using a seed on exfoliated graphene/SiO₂/Si.

FIG. 67 shows the molecular structure of F₁₆CuPc.

In the accompanying drawings, like reference characters refer to the same or similar parts throughout the different views; and apostrophes are used to differentiate multiple instances of the same or similar items sharing the same reference numeral. The drawings are not necessarily to scale, emphasis instead being placed upon illustrating particular principles, discussed below.

### DETAILED DESCRIPTION

The foregoing and other features and advantages of various aspects of the invention(s) will be apparent from the following, more-particular description of various concepts and specific embodiments within the broader bounds of the invention(s). Various aspects of the subject matter introduced above and discussed in greater detail below may be implemented in any of numerous ways, as the subject matter is not limited to any particular manner of implementation. Examples of specific implementations and applications are provided primarily for illustrative purposes.

Unless otherwise defined, used or characterized herein, terms that are used herein (including technical and scientific terms) are to be interpreted as having a meaning that is consistent with their accepted meaning in the context of the relevant art and are not to be interpreted in an idealized or overly formal sense unless expressly so defined herein. For example, if a particular composition is referenced, the composition may be substantially, though not perfectly pure, as practical and imperfect realities may apply; e.g., the potential presence of at least trace impurities (e.g., at less than 1 or 2%, wherein percentages or concentrations expressed herein can be either by weight or by volume) can be understood as being within the scope of the description; likewise, if a particular shape is referenced, the shape is intended to include imperfect variations from ideal shapes, e.g., due to manufacturing tolerances.

Although the terms, first, second, third, etc., may be used herein to describe various elements, these elements are not to be limited by these terms. These terms are simply used to distinguish one element from another. Thus, a first element, discussed below, could be termed a second element without departing from the teachings of the exemplary embodiments.

Spatially relative terms, such as “above,” “below,” “left,” “right,” “in front,” “behind,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

Further still, in this disclosure, when an element is referred to as being “on,” “connected to” or “coupled to” another element, it may be directly on, connected or coupled to the other element or intervening elements may be present unless otherwise specified.

The terminology used herein is for the purpose of describing particular embodiments and is not intended to be limiting of exemplary embodiments. As used herein, singular forms, such as “a” and “an,” are intended to include the plural forms as well, unless the context indicates otherwise. Additionally, the terms, “includes,” “including,” “comprises” and “comprising,” specify the presence of the stated elements or steps but do not preclude the presence or addition of one or more other elements or steps.

Layered transition metal dichalcogenides (LTMDs), including MX₂ (where M=Mo or W and where X=S, Se or Te), have attracted extensive research efforts in the fields of nanotribology, catalysis, energy harvesting, and optoelectronics. Monolayers of two-dimensional crystals, such as graphene, have been highlighted regarding both scientific and industrial aspects due to novel physical phenomenon inherited from the reduced dimensionality. Similarly, the broken inversion symmetry and the indirect-to-direct bandgap transition of layered transition-metal dichalcogenides are observed when the dimension is reduced from multilayers to a monolayer. The layered transition-metal dichalcogenide monolayers (being considered as the thinnest semiconductors) exhibit great potential for advanced short-channel devices.

A transistor fabricated with an exfoliated MoS₂ monolayer displays a high on-off current ratio and good electrical performance, both of which are advantageous for an electronic circuit requiring low stand-by power. Recent theoretical predictions suggest that the dissociation of H₂O can be realized at defects in single-layer MoS₂, which is highly advantageous for developing clean and sustainable energy from hydrogen. Moreover, monolayer MoS₂ and WS₂ have been considered as ideal materials for exploring valleytronics and valley-based optoelectronic applications. The broken inversion symmetry of the monolayer and the strong spin-orbit coupling lead to a fascinating interplay between spin and valley physics, enable simultaneous control over the spin and valley degrees of freedom, and create an avenue toward the integration of spintronics and valleytronics applications.

The synthesis of a layered transition-metal dichalcogenide monolayer may be achieved using various aromatic molecules as seeds on a growth substrate. Using an aromatic-molecule seed with high thermal stability and exercising better control of the seeding treatment on surfaces can overcome the challenges associated with the synthesis of a high-quality layered transition-metal dichalcogenide monolayer. Additionally, a robust transfer technique that avoids degradation in quality and contamination is presented that is particularly advantageous for fundamental physics and optoelectronic applications. Particular embodiments, described herein, demonstrate that high-quality MS₂ monolayers can be directly synthesized on various surfaces using a scalable APCVD process with the seeding of perylene-3,4,9,10-tetracarboxylic acid tetrapotassium salt (PTAS). Not only is the growth successful on surfaces of different materials, but it has been found that the deposition method is also applicable for surfaces with various morphologies. The as-synthesized MS₂ monolayer exhibits a single crystalline structure with a specific flake shape even on amorphous surfaces. Meanwhile, a reliable transfer technique is also presented herein to enable MS₂ monolayer growth on flexible substrates or surfaces of various functional materials while maintaining their high quality. In additional embodiments (discussed, below), the same or similar techniques can be used to seed the substrate with F₁₆CuPc molecules, together with or in place of PTAS.

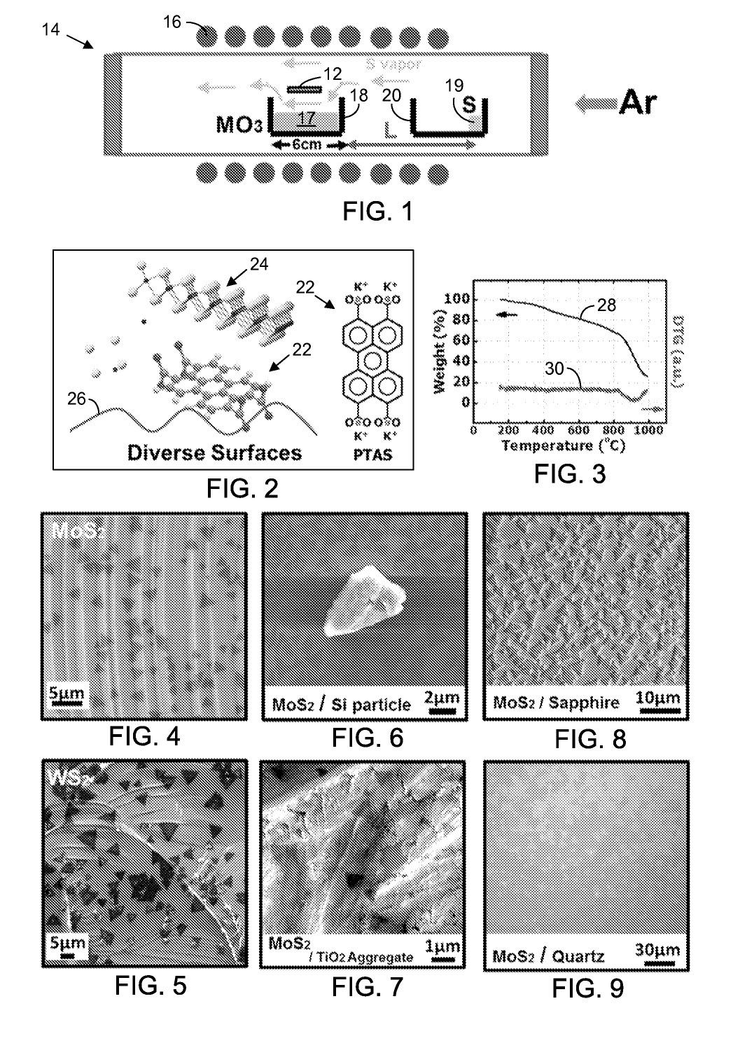

A schematic illustration of an experimental setup for forming an MoS₂ monolayer is shown in FIG. 1, wherein a substrate 12 is passed through a furnace 14 with an argon atmosphere and with heating elements 16 that supply heat to vaporize MoO₃ and S for deposition onto the substrate 12. In one embodiment, high-purity MoO₃ (99%, Aldrich), WO₃ (99%, Alfa), and S powder (99.5%, Alfa) are used as starting reactants. The MO₃ (where M=Mo or W) powders 17 and S powders 19 are placed in different crucibles 18 and 20.

FIG. 2 shows the chemical formula of the PTAS 22 and a schematic diagram for an exemplary growth mechanism for PTAS 22 and MS₂ 24 on a surface 26. The high solubility of PTAS in water enables the seed solution to be uniformly distributed on hydrophilic growth-substrate surfaces. Compared to many other aromatic molecules, PTAS survives well at a higher temperature. In FIG. 3, thermogravimetric analysis (TGA) of PTAS demonstrates good thermal stability and a slow decomposition rate when the growth temperature is below 820° C.; both the remaining percentage weight 28 of the PTAS and derivative thermogravimetry (DTG) 30 are plotted. Both MoS₂ and WS₂ can be directly grown on corrugated surfaces of Si as shown in FIGS. 4 and 5. Moreover, the growth of MoS₂ on diverse surfaces, including Si particles, TiO₂ nano particles, sapphire, and quartz, displays a similar growth behavior, as shown in FIGS. 6 and 7, respectively. A scanning-electron-microscope (SEM image) of monolayer MoS₂ on sapphire is provided in FIG. 8, while an optical microscope (OM) image of monolayer MoS₂ on quartz is provided in FIG. 9.

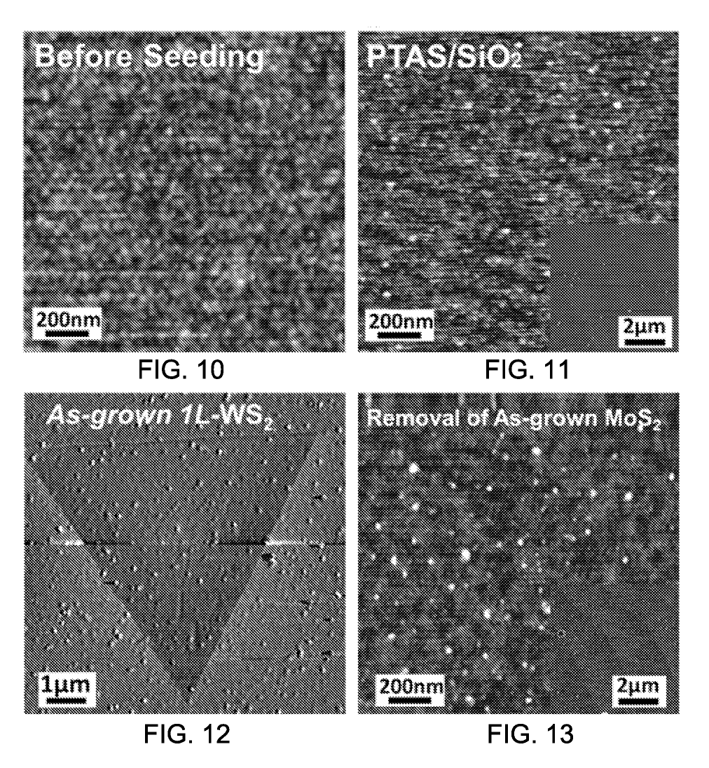

An atomic-force-microscopy (AFM) image of the surface of a SiO₂/Si substrate prior to seed treatment is provided in FIG. 10. The distribution and morphology of the PTAS seeds on this surface is monitored with atomic force microscopy (AFM), as shown in FIG. 11. After drying the solvent, uniform and tiny seeds of PTAS appear on the surfaces. Some randomly distributed aggregation of seeds is also observed in the inset of FIG. 11. The particle-like aggregation of PTAS may provide a nucleation site to host the MoS₂ nuclei; and, then, further layer growth is rapidly activated under the growth conditions specified herein.

The nucleation of MoS₂ nuclei may be the rate-controlling step for the seed-initiated-growth of MoS₂ layers for the following reasons. First, an as-synthesized MX₂ layer can directly grow over small amounts of seeds, as shown in FIG. 12. An AFM image of the surface of the substrate of FIG. 12 after removal of the as-grown MoS₂ monolayer is provided in FIG. 13.

Second, a reduced growth time facilitates single-layer MoS₂ growth, and avoids further growth of MoS₂ to larger thickness. Third, further growth prefers to take place at the nucleation site, as shown in the inset of FIG. 19. The island in the center is formed with the same edge orientation as that underneath MoS₂ flake, which is also a strong indication to support this idea of preferred growth initiation, and it is consistent with the single-crystal nature of MoS₂.

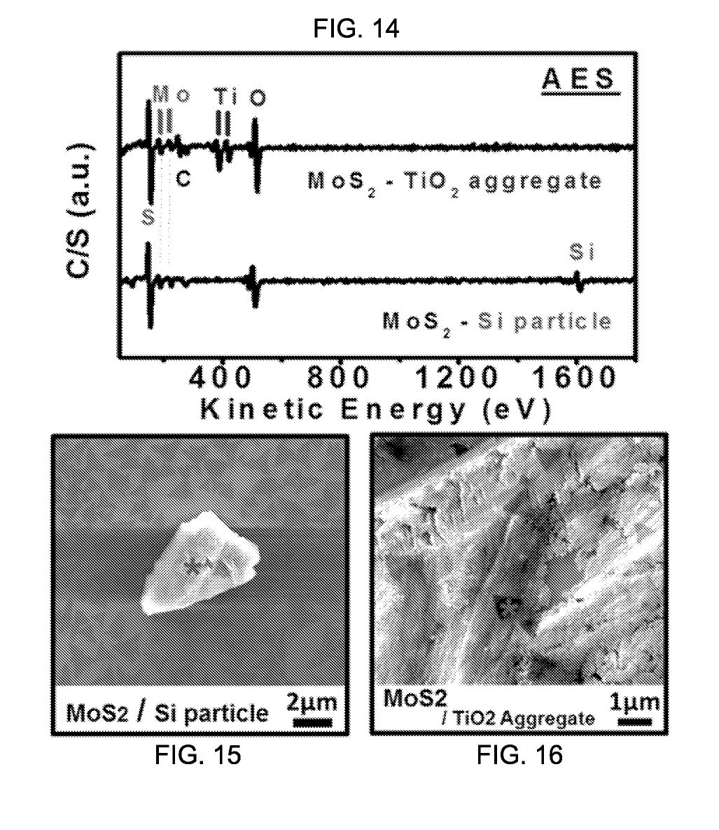

In various embodiments, the flakes can be grown on a surface of a growth substrate selected from the cleaved side-wall of a silicon substrate, the surface of micron-sized silicon particles, and an aggregation of TiO₂ nanoparticles. Furthermore, the flakes all show triangular shapes, which have been confirmed by transmission electron microscope (TEM) analysis to be single-crystalline domains. A Nano-Auger electron microscope (Nano-AES, Phi) is employed to significantly verify the existence of MS₂ layers on various surfaces, as shown in the plots of FIG. 14. The nano-AES experiment is carried out with a working voltage of 10 kV in a UHV environment. The AES signals mainly come from the surfaces within a 5 nm depth and a spot size less than 10 nm, enabling their identification with high accuracy and resolution.

In particular embodiments, 0.01 g water-soluble anatase-TiO₂ nanoparticles (T-nps, MK Impex Co) are mixed into the PTAS solution (100 μM) by sonication for 5 minutes. Prior to the growth, a drop of the mixture solution of T-nps and PTAS is placed on the SiO₂/Si (i.e., silicon coated with a 300-nm layer of silica) substrate and dried with blowing N₂ air. Further growth procedures are the same as for the growth of MoS₂. A magnified image of MoS₂ grown on silicon particles is provided in FIG. 15, and a magnified image of MoS₂ grown on a TiO₂ aggregate is provided in FIG. 16.

With this better understanding of the synthesis process as well as the initial growth of MoS₂, synthesis of a monolayer MX₂ single crystal is achievable by controlling the nucleation and growth rate of MoS₂. The selection of an appropriate seed (e.g., with high thermal stability) and better control of the surface seeding process facilitates realization of this goal. In this work, PTAS is highlighted and selected as the seeds for these initial experiments, because its high solubility in water enables the seed solution to be uniformly distributed on diverse hydrophilic surfaces. Moreover, the thermal analysis and the AFM image (FIG. 13) of the surface after removal of the as-grown MoS₂ verify the stability and existence of the seeds.

It is worth noting that the synthesis process involves surface reactions among the reactants, and the synthesis process is governed by many factors including the seed density, seed size and gas flow. This study, however, shows that the synthesis of high-quality transition metal dichalcogenide (TMD) single layers is achievable with extremely high reproducibility.

The MS₂ layers were synthesized on diverse substrates with APCVD. The PTAS solution was synthesized using perylene-3,4,9,10-tetracarboxylic dianhydride (PTCDA) following the procedures specified in W. Wang, et al., “Aqueous Noncovalent Functionalization and Controlled Near-Surface Carbon Doping of Multiwalled Boron Nitride Nanotubes,” J. Am. Chem. Soc., 130, 8144-8145 (2008). The substrates for the growth were pre-treated with piranha solution (i.e., a 3:1 mixture of concentrated sulfuric acid to 30% hydrogen peroxide solution); and the surface residuals were removed via sonication in acetone, IPA and DI water for 10 minutes. Prior to growth of the monolayer, a droplet of aqueous PTAS solution was spun on the substrates; and a gentle blow of gas on the substrate enabled the droplet to spread and uniformly precipitate into tiny seeds on the surfaces of the various substrates. The MoS₂ and WS₂ layers were respectively synthesized at 650 and 800° C. for 5 minutes with a heating rate of 15° C./min and argon (Ar) flow at ambient pressure. Detailed parameters for this process are listed in Table 1, where the gas-flow rate is reported in standard cubic centimeters per minute (sccm), and where L is the distance between crucibles.

TABLE 1

| | | Seed | Gas- | | | |
|---|---|---|---|---|---|---|
| Monolayer | Temp. | concen- | flow | | | |
| composition | (° C.) | tration | rate | MO₃ | S | L |
| MoS₂ | 650 | 100 μM | 10 sccm | 0.03 g | 0.01 g | 18 cm |
| WS₂ | 800 | 1 mM | 5 sccm | 1 g | 0.015 g | 20 cm |

At the growth temperature, MO₃ powders were reduced by sulfur vapor to form volatile MO₃₋ₓ. Substrates were facing down on the crucible, and the arriving MO₃₋ₓ molecules reacted with sulfur vapor to form MS₂ on the substrates. Without the seeds, only island growth of MoS₂ particles was observed on bare SiO₂ surfaces. In contrast, the presence of PTAS on the surface enabled continuous layer growth, possibly via assisting the adsorption of molecules and the initiation of heterogeneous nucleation.

As shown in FIGS. 4-9, as-grown MoS₂ shows great flexibility and tolerance in response to surface corrugations. In FIGS. 4 and 5, MS₂ flakes were uniformly grown on the cleaved side wall of silicon (Si) substrates. Most of the MoS₂ flakes are single-layer, while WS₂ flakes exhibited a slight variation in the number of layers. In FIG. 6, a micron-sized Si particle is covered with single-layer MoS₂ flakes. FIG. 7 shows that the growth of MoS₂ flakes can even be achieved on aggregations of TiO₂ nanoparticles.

Nano-Auger electron spectroscopy was utilized to verify the existence of MS₂ layers, as shown in FIG. 14. Furthermore, the growth of monolayer MoS₂ is achievable on crystalline surfaces, including quartz and sapphire, as shown in FIGS. 8 and 9. The triangular single-layer MoS₂ flakes, as shown in FIG. 15, were commonly observed in the early stages of the growth. The ability to synthesize a layered transition-metal dichalcogenide monolayer with high tolerance to surface corrugation on diverse surfaces opens a route toward the synthesis of hetero- and composite structures. An SEM image of the as-grown MoS₂ on an aggregation of TiO₂ nanoparticles is shown in FIG. 16.

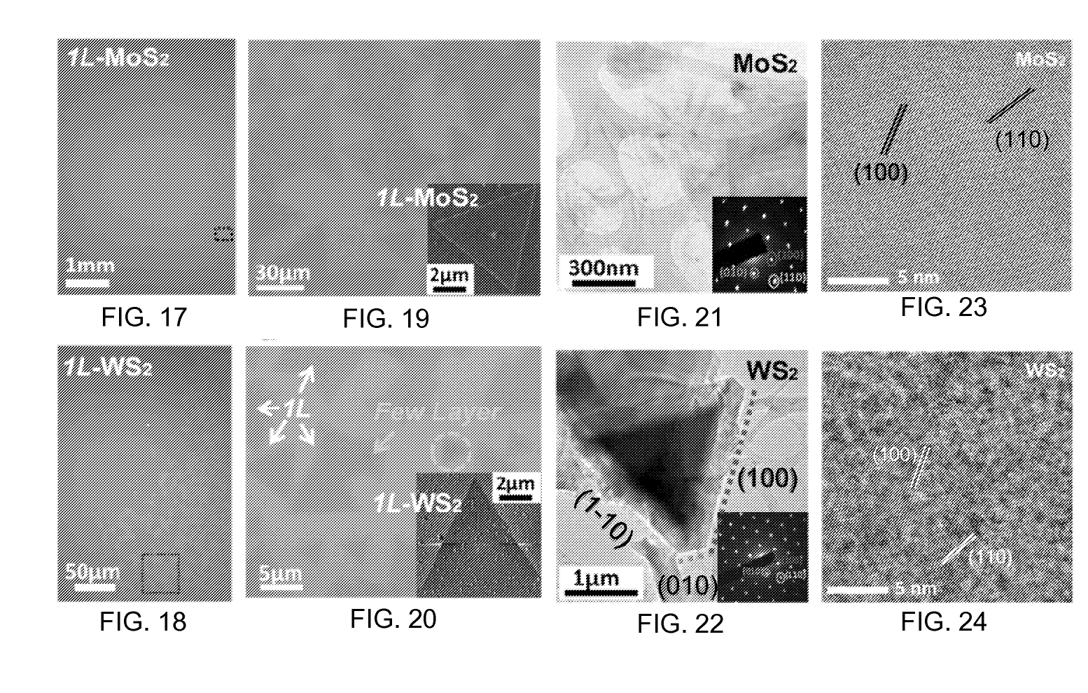

In FIGS. 17 and 18, uniform MoS₂ and WS₂ monolayers were grown on SiO₂/Si substrates using the methods described herein; and the as-grown MoS₂ and WS₂ monolayers had dimensions of greater than 1 cm and greater than 100 μm, respectively. The isolated MS₂ flakes appeared on the edge regions of the substrates (as shown in FIGS. 19 and 20, where the insets show AFM images of MoS₂ and WS₂ monolayers with thicknesses of 0.71 and 0.86 nm, respectively). In the inset of FIG. 19, there is an island in the center formed with the same edge orientation as the underlying MoS₂ flake, which is consistent with its single-crystal geometry.

Here, the nucleation is the rate-controlling step in the seed-initiated growth process. Additionally, the growth of MS₂ favoring layer growth in the initial growth stage with PTAS seeding is demonstrated by the as-synthesized WS₂ monolayer over small amounts of seeds (as shown in the inset of FIG. 20) and by additional observation of an as-grown large-area monolayer.

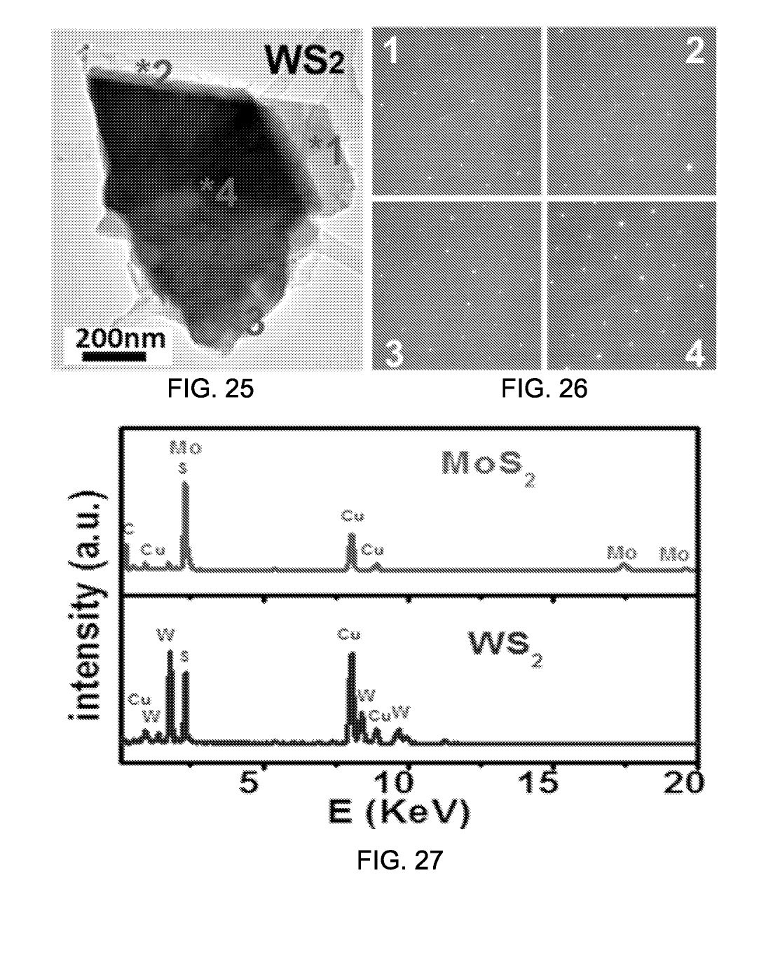

The crystal structure and edge structure of the as-grown MS₂ flakes were studied with a transition electron microscope (TEM). In FIGS. 17-24, high-resolution TEM images and the corresponding selected-area-electron-diffraction (SAED) pattern with a [001] zone reveals the same hexagonal lattice structure and a similar lattice spacing for MoS₂ and WS₂. The spacing of (100) and (110) planes of both materials are 0.27 and 0.16 nm, respectively. FIG. 22 shows that the domain facets clearly align along (100), (010), and (1-10) planes. In FIG. 25, a few-layer WS₂ flake is shown, and the selected-area-electron-diffraction patterns at different locations indicate that the flake is single-crystal without any mis-orientations in the stacking of the layers. The single-crystal structure and specific edge structures are advantageous to explore fundamental edge states in this class of materials.

A field-emission transmission electron microscope (JEOL JEM-2100F, operated at 200 kV with a point-to-point resolution of 0.19 nm) equipped with an energy dispersive spectrometer (EDS) was used to obtain information regarding the microstructures and the chemical compositions of the formed layers. The TEM samples were prepared using lacy-carbon Cu grids and suspended MS₂ nanosheets in DI water. In FIG. 26, the selected-area-electron-diffraction (SAED) patterns with a [001] zone were taken at four different areas, as marked in FIG. 25. Distinct selected-area-electron-diffraction patterns with the same orientation are seen in the areas with different thicknesses, indicating that the few-layer triangular domain is a single-crystal without any mis-orientations in the stacking of layers. The transmission-electron-microscope energy-dispersive x-ray (TEM-EDX) spectra of the as-grown MoS₂ (top) and WS₂ (bottom) is provided in FIG. 27.

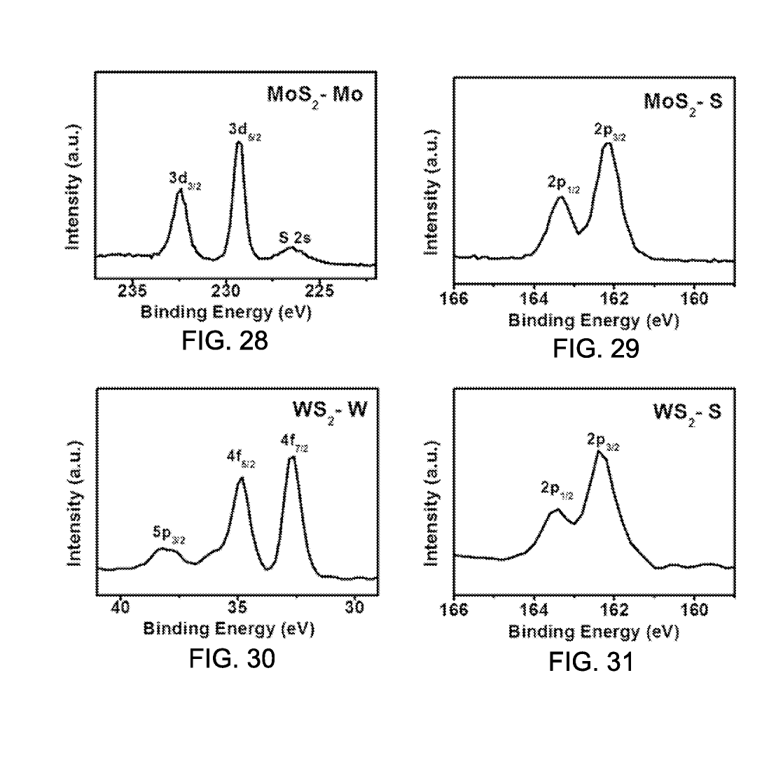

The x-ray photoelectron spectra for the molybdenum (Mo) 3d orbit of the as-grown MoS₂ is plotted in FIG. 28; the x-ray photoelectron spectra for the sulfur (5) 2p orbits of the as-grown MoS₂ is plotted in FIG. 29; the x-ray photoelectron spectra for the tungsten (W) 4f orbits of the as-grown WS₂ is plotted in FIG. 30; finally, the x-ray photoelectron spectra for the sulfur (5) 2p orbits of the as-grown WS₂ is plotted in FIG. 31.

The spectroscopy and photoluminescence (PL) performance of the as-grown MS₂ are evidenced by the Raman and photoluminescence mapping in confocal measurements shown in FIGS. 35 and 36. Raman spectra and photoluminescence were obtained by confocal Raman microscopic systems (NT-MDT), specifically in a confocal spectrometer using a 473-nm excitation laser. The wavelength and spot size of the laser were 473 nm and 0.4 μm, respectively. The silicon peak at 520 cm⁻¹ was used for calibration in these experiments. Raman and photoluminescence mapping was constructed by plotting the integrated MS₂ Raman peak intensity (360˜420 cm⁻¹ for MoS₂, 330˜440 cm⁻¹ for WS₂) and the photoluminescence intensity (640˜700 nm for MoS₂, 600˜680 nm for WS₂) in the confocal measurements. The thermal stability of PTAS was examined by thermogravimetric analysis (TGA, TA Instrument TGA2950) with an argon flow. The PTAS solution was heated and kept at 150° C. for 30 minutes to remove the solvent of water. Then, the PTAS was heated to 1000° C. with an increasing rate of 10° C./min.

The surface morphology of the samples was examined with an optical microscope (OM), a commercial atomic force microscope (AFM, Digital instrument 3100), and a scanning electron microscope (SEM, FEI VS600). Device characterization was performed using an Agilent 4155C semiconductor parameter analyzer and a Lakeshore cryogenic probe station with micromanipulation probes.

A similar process was carried out for field-effect transistors (FETs) of MoS₂ and WS₂ monolayers deposited via CVD. First, poly(methyl methacrylate) (PMMA, 950 k MW) resist was spun on the as-grown MS₂ samples and patterned using standard electron-beam lithography. Metal stacks of 5-nm Ti/50-nm Au were then deposited to form direct contact with the as-grown MoS₂ and WS₂, followed by lift-off of the layers after contact. The FETs of the as-grown WS₂ monolayers were measured under ultraviolet radiation to extract their carrier density from the Schottky contacts between WS₂ and the metal electrodes. All measurements were taken in a low-pressure vacuum (with a pressure of ˜10⁻⁵ Torr) at room temperature to reduce the hysteresis.

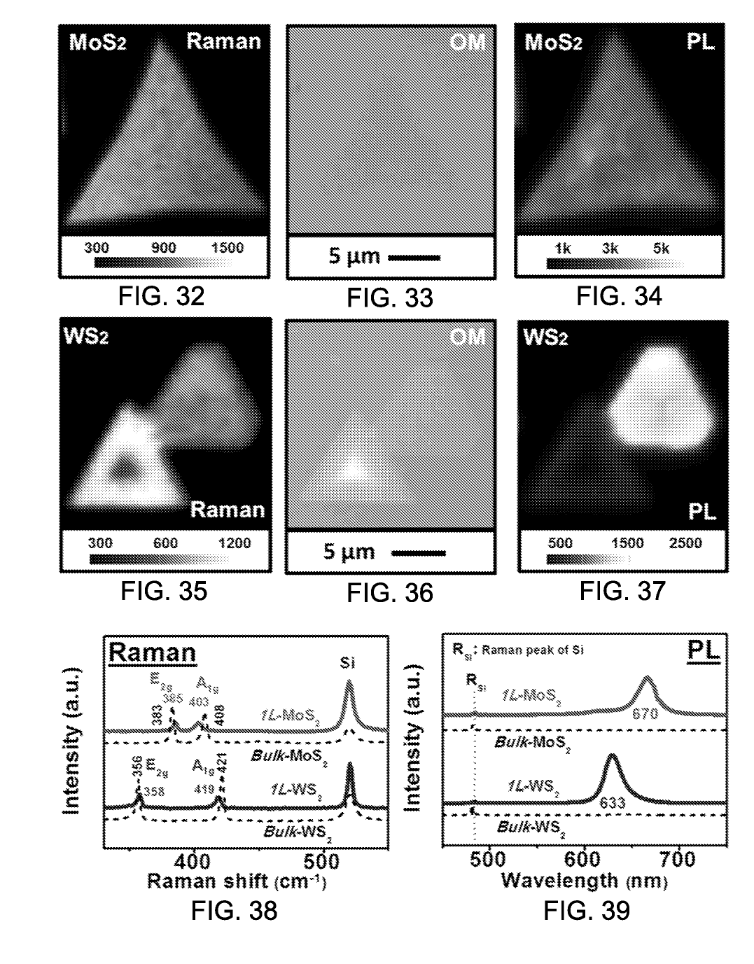

A uniform contrast and strong intensity are observed in the Raman plots (i.e., FIGS. 32 and 35) and in the photoluminescence mapping plots (i.e., FIGS. 34 and 37), implying that the MS₂ exhibits high crystallinity and high uniformity. The A_{1g} Raman mode is very sensitive to layer number, and the peak frequency difference between the E_{2g} and A_{1g} modes can be used to identify the layer number of MoS₂. In FIG. 35, the E_{2g} and A_{1g} modes of the Raman band of single-layer MoS₂ are located at 385 and 403 cm⁻¹, respectively, with full-width-half-maximum (FWHM) values of 3.5 and 6.6 cm⁻¹, while those of the bulk MoS₂ are at 383 and 408 cm⁻¹ with FWHM values of 4.1 and 3.3 cm⁻¹. In contrast, the Raman E_{2g} and A_{1g} energies of WS₂ are less sensitive to layer thickness, where the E_{2g} and A_{1g} modes of single-layer WS₂ are located at 358 and 419 cm⁻¹ with FWHM values of 4.3 and 5.3 cm⁻¹, while those of bulk WS₂ are at 356 and 421 cm⁻¹ with FWHM values of 3.6 and 3.5 cm⁻¹, respectively, as shown in FIG. 38.

The Raman intensity of MS₂ increases with thickness, whereas the photoluminescence intensity of MS₂ rapidly decreases with an increase in layer number (compare FIG. 35 with FIG. 36). As shown in FIG. 39, the photoluminescence (PL) peaks of as-grown MoS₂ and WS₂ are approximately located at 670 and 633 nm, which is consistent with the published bandgap. Note that the photoluminescence peak of single-layer MS₂ is much stronger than the Raman signal, indicating high crystallinity and a low defect concentration in the as-grown MS₂ monolayer.

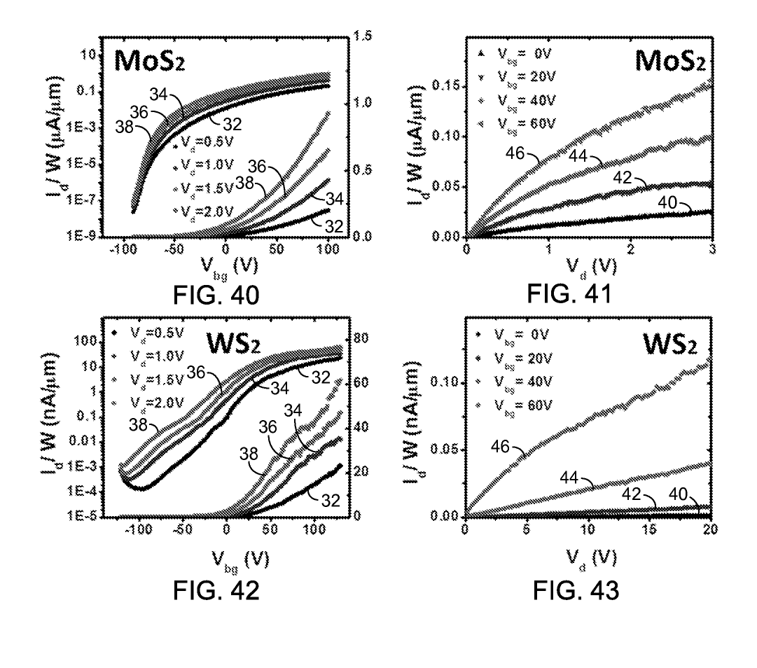

To evaluate the electrical performance of the as-grown MS₂ monolayer, we fabricated bottom-gated transistors with the as-grown samples on SiO₂/Si. FIGS. 40-43 show a typical electrical performance of MS₂ field-effect transistors (FETs). Both compositions show n-type behavior. In FIGS. 40 and 42, V_{d}=0.5 V is plot 32; V_{d}=1.0 V is plot 34; V_{d}=1.5 V is plot 36; and V_{d}=2.0 V is plot 38. In FIGS. 41 and 43, V_{bg}=0 V is plot 40; V_{bg}=20 V is plot 42; V_{bg}=40 V is plot 44; and V_{bg}=2.0 V is plot 46.

The field-effect electron mobility is extracted from the linear regime of the transfer properties using the equation, μ=[dI_{d}/d V_{bg}]×[L/(WCₒₓV_{d})], where L, Wand Cₒₓ are the channel length, width and the gate capacitance per unit area, respectively. Here, L=1 μm. From the characteristics of the MoS₂ FET shown in FIG. 40, the on-off current ratio exceeds 10⁷, and the mobility is up to 1.2 cm²/V·s, which is comparable to an exfoliated MoS₂ monolayer fabricated without high-k dielectrics. The excellent electrical performance of the MoS₂ FET demonstrates low defects and the high quality of this single-layer MoS₂. To estimate the doping level of as-grown MoS₂, the source/drain current at zero gate voltage was modeled as I_{d}=qn_{2D}Wμ(V_{d}/L), where n_{2D} is the two-dimensional carrier concentration; q is the electron charge; μ is the calculated mobility; and V_{d} is the source/drain voltage, respectively. From the output characteristics of as-grown MoS₂ (FIG. 41), n_{2D} is extracted to be ˜5.2×10¹⁰ cm⁻². FIGS. 42 and 43 show the electrical characterizations of WS₂ FETs. The on-off ratio is approximately 10⁵, and the mobility is around 0.01 cm²/V·s, which is relatively low compared to that of the MoS₂-based FET. Since, however, this is believed to be the first FET based on CVD-grown WS₂, the metal electrodes may be optimized in the future to improve the performances.

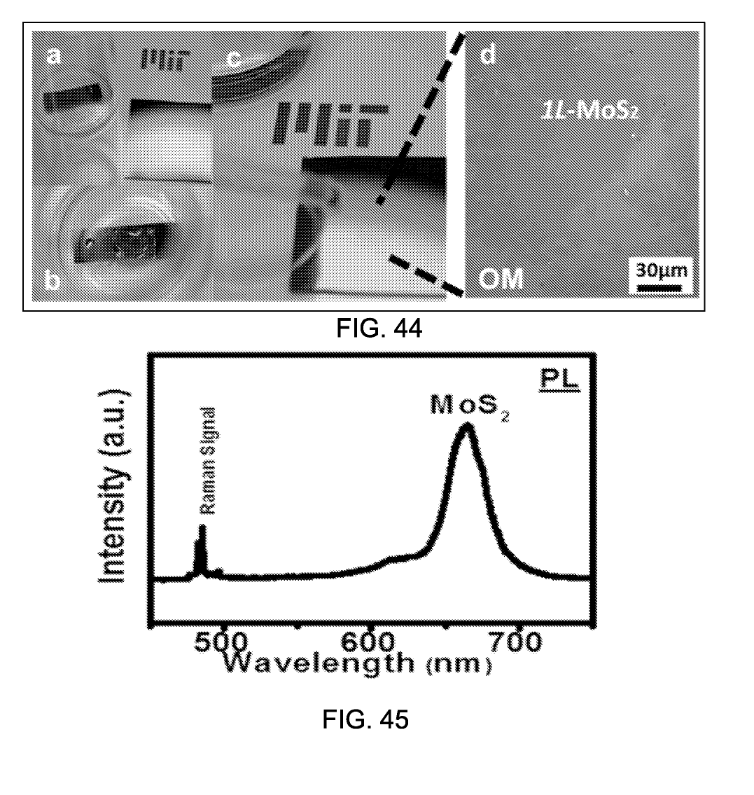

FIG. 44 demonstrates the mass production of single-layer MoS₂ nanosheets in de-ionized (DI) water. After a sample of an as-grown MoS₂ monolayer on a SiO₂/Si growth substrate was put into a bottle [as shown in image (a)], DI water was added to the bottle [as shown in image (b)] and passed underneath the MoS₂ monolayer, causing the MoS₂ monolayer to rapidly peel off the growth substrate at different locations and break into small flakes that were suspended in the solution. A solution of MoS₂ nanosheets was thus formed; and, in image (c), a drop of this solution was put onto another (clean) SiO₂/Si target substrate using a pipette. After a gentle heating at 50° C. to dry off the target substrate, the deposited MoS₂ flakes were found on the surface of the SiO₂/Si target substrate with a flake size ranging from 1-60 μm, as shown in image (d). Moreover, these transferred MoS₂ flakes retained their excellent photoluminescence performance and Raman intensity (as shown in FIG. 45), suggesting that the water-only transfer can extensively avoid damage and contamination in the transfer process, which points to a simple way to achieve mass production of high-quality layered transition-metal dichalcogenide nanosheets without any additional treatments or annealing.

As the growth temperature of MS₂ monolayers are relatively high, temperature-sensitive substrates (such as polymer-based substrates) were not used in the growth stage of this synthetic process. It is advantageous to develop a transfer technique to implement large-area MS₂ on even more versatile types of substrates. Here, we report a transfer technique that maintains the quality of the as-grown monolayer.

In one exemplification, an as-grown MoS₂ monolayer sample and underlying growth substrate was cut into three pieces, and these samples were respectively treated with de-ionized (DI) water, isopropyl alcohol (IPA), and acetone for 30 seconds. The surface of the as-grown monolayer was hydrophobic, so the IPA and acetone respectively spread out on the second and third MoS₂ monolayers, whereas the water remained in droplet form on the first MoS₂ monolayer. During the 30 seconds of exposure to the water, the first as-grown MoS₂ monolayer started breaking into small pieces and floating on the water droplet. Thus, the as-grown MoS₂ monolayer can be easily removed from the growth substrate with DI water. We did not observe such lift-off behaviors for the organic solvents used with the second and third samples. It is suspected that the DI water in the MoS₂-substrate interface assists the lift-off of the MoS₂ monolayer from the growth substrate because of the high solubility of PTAS in water and because of the hydrophobic surfaces of MoS₂.

The transfer of the entire monolayer was also demonstrated using polydimethylsiloxane (PDMS), as a transfer medium, and water. The polydimethylsiloxane transfer layer can be applied and adhered to the monolayer, while monolayer is still attached to the growth substrate. As the seeding layer is dissolved, the (clean and continuous) monolayer is released with the transfer layer still adhered into the water in which it is immersed. Using the polydimethylsiloxane layer as a stamp, the transfer of MS₂ monolayers to other substrates can be implemented. Single-layer MoS₂ can be well transferred to highly ordered pyrolytic graphite (HOPG) or to a flexible polyethylene terephthalate (PET) target substrate with direct stamping (wherein the single-layer MoS₂ is removed with DI water; polydimethylsiloxane is attached to the MoS₂ surface, and the MoS₂ layer is then stamped onto the target substrate), which may enhance developments in flexible optoelectronics and STM-related studies. When the MoS₂ monolayer is transferred to a target substrate, the polydimethylsiloxane transfer layer can be peeled off, leaving the MoS₂ monolayer exposed on the target substrate.

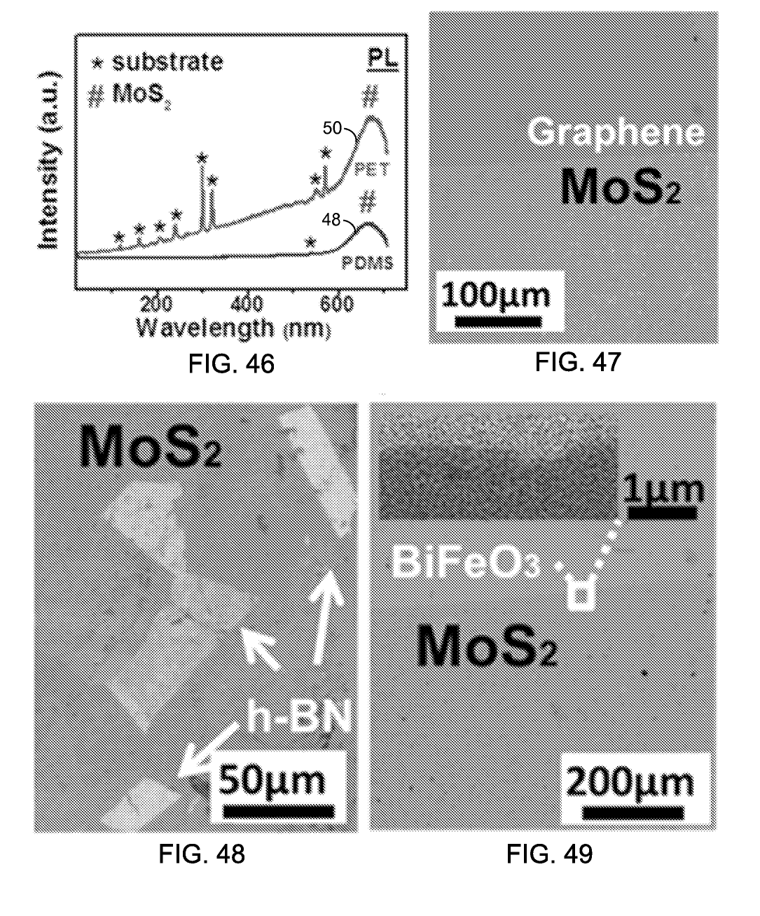

Strong photoluminescence of the transferred MoS₂ monolayer on polydimethylsiloxane (PDMS) 48 and polyethylene terephthalate (PET) 50 surfaces is observed in FIG. 46, illustrating that the quality of the MoS₂ monolayer was maintained after its removal from the growth substrate. Since only a drop of water was involved in the transfer process, contamination was avoided. Moreover, hybrid structures based on a layered transition-metal dichalcogenide monolayer and functional materials, including conductive graphene, insulating h-BN, and multiferroic BiFeO₃, were successfully fabricated using direct stamping, as shown in FIGS. 47-49. Thus, this approach may stimulate development of various novel hybrid structures and functional materials based on layered transition-metal dichalcogenide monolayers.

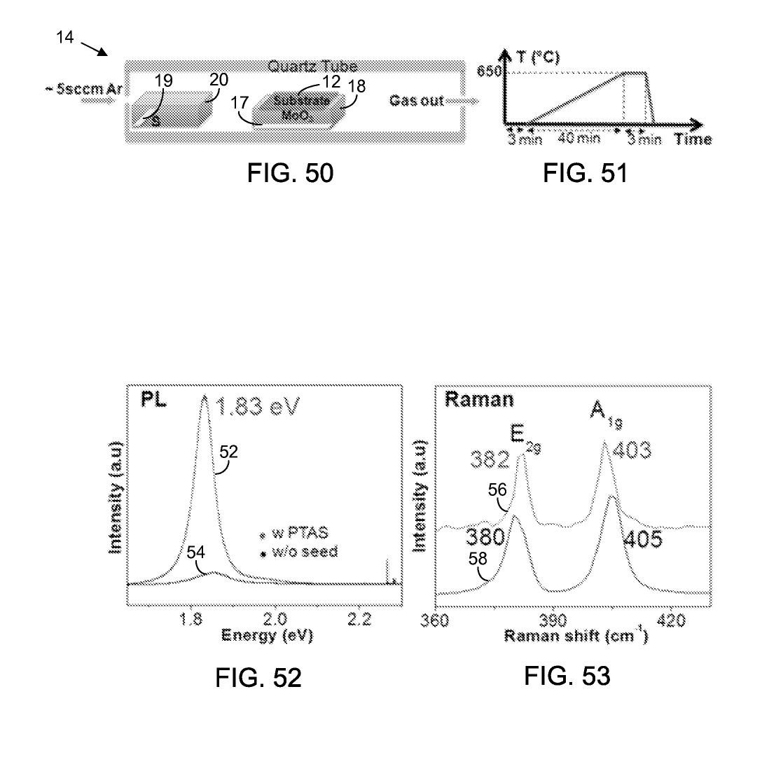

A schematic illustration of a CVD system for depositing MoS₂ is provided in FIG. 50, and a plot of a temperature programming process used for MoS₂ growth is provided in FIG. 51. Additionally, FIG. 52 plots the photoluminescence spectrum of MoS₂ grown samples prepared with PTAS seed (top plot) and without seed (lower plot), where the excitation wavelength is 532.5 nm. Further, FIG. 53 plots the Raman spectrum of MoS₂ grown samples prepared with PTAS seed (top plot) and without seed (lower plot), where the excitation wavelength is 532.5 nm.

FIG. 50 shows an illustration of a CVD setup for MoS₂ growth, and typical growth conditions (time-temperature profile) is shown in FIG. 51. Briefly, 0.018 g MoO₃ (molybdenum oxide) powder 17 in a ceramic crucible 18 was placed in the hot zone center of the furnace 14. 0.016 g sulfur powder 19 was placed in the crucible 20 in a distance 15 cm away from the heating center. The substrate 12 was face down on the top of the MoO₃ powder 17. The growth temperature was controlled at around 650° C. A continuous, large-area MoS₂ monolayer was achieved using PTAS as seed. In contrast, only MoS₂ particles were observed on the substrate without using a seed. At the edge of the continuous film, the isolated triangular MoS₂ domains in a size of about 50 μm were found. For the MoS₂ particles, the height range was from 1-200 nm, which was confirmed with atomic force microscopy (AFM).

The obtained MoS₂ monolayer and particles have been further characterized by photoluminescence (PL) and Raman spectroscopy. As shown with plot 52 in FIG. 52, the MoS₂ layers grown by using PTAS as a seed exhibit an intense PL at around 1.83 eV with a FWHM (full width at half maximum intensity) of about 55 meV, which is consistent with a direct bandgap of the monolayer MoS₂ and is an indication of the high-quality of the MoS₂ monolayer. In contrast, a weak PL intensity of the MoS₂ particles without using PTAS as seed, as shown with plot 54, is identified as being due to the indirect bandgap of multilayer MoS₂.

The corresponding E_{2g} and A_{1g} modes of the Raman band of MoS₂ 56 are shown in FIG. 53. The frequency difference between these two modes depends on the number of layers of the MoS₂ sample, which is about 20 cm⁻¹ for monolayer MoS₂ and about 25 cm⁻¹ for the bulk MoS₂. Here, the fitting results show that these two modes are located at 382 and 403 cm⁻¹ for the MoS₂ layer 56, where the frequency difference is about 21 cm⁻¹, while they are at 380 and 405 cm⁻¹ with a frequency difference of 25 cm⁻¹ for the MoS₂ particles 58. These results further indicate that by using PTAS as a seed, MoS₂ monolayer 56 growth can be easily obtained, while, without using the seed, MoS₂ particle 58 growth is preferred. The comparative results suggest that the PTAS seed plays an important role in the monolayer MoS₂ growth and also facilitates the layer rather than island growth in these embodiments.

Since the seed, rather than the substrate, is the crucial factor for growing large-area and high-quality MoS₂, this suggests that we can grow MoS₂ on diverse substrates if an appropriate seed is put on the substrate. This is very good news for the possibility of construction of hybrid structures. The hybrid structures between transition-metal-dichalcogenide monolayer, graphene-like 2D material and some functional materials, such as graphene, h-BN and metals, have some attractive properties for applications of logic transistors and high performance electronic and optoelectronic devices.

PTAS exhibits excellent properties as a seed for promoting MoS₂ growth on the hydrophilic substrate, since it is dissolved in a water solution; while the F₁₆CuPc seed, described here, performed well on the hydrophobic substrate, since it has strong interaction with hydrophobic surfaces and can be deposited uniformly by vacuum thermal evaporation. Therefore, these two kinds of seeds are complementary to each other and can therefore meet most of the requirements in the future applications.

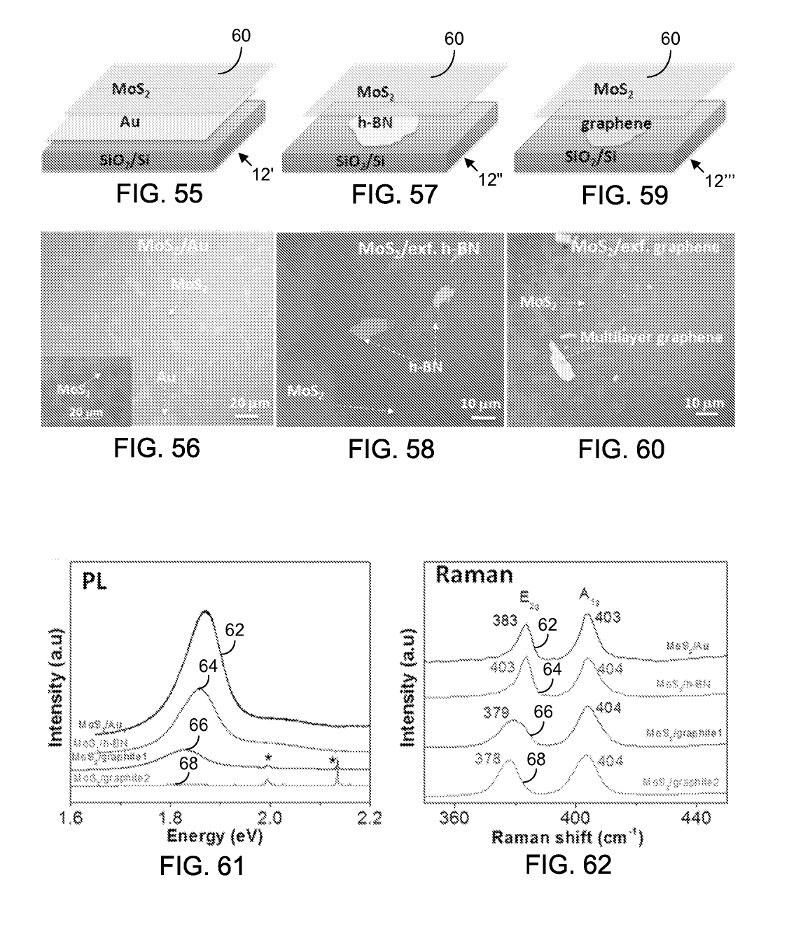

FIGS. 55 and 56 show a schematic and optical image of MoS₂ 60 grown directly on a 100-nm Au/SiO₂/Si substrate 12′. FIGS. 57 and 58 show a schematic and optical image of MoS₂ 60 grown on an exfoliated h-BN/SiO₂/Si substrate 12″. FIGS. 59 and 60 show a schematic and optical image of MoS₂ 60 grown on an exfoliated graphene/SiO₂/Si substrate 12′″. Seeding for growing these layers 60 was provided by evaporating 2 Å F₁₆CuPc on the substrates. The resulting whole surface of the substrates 12 in this case was covered by continuous film.

The PL and Raman spectra were collected on the area with Au, h-BN and graphene (graphite), as shown in FIGS. 61 and 62, which includes plots for treated substrates formed of MoS₂/Au 62, MoS₂/h-BN 64, MoS₂/graphite1 66, and MoS₂/graphite2 68. The PL signal and the E_{2g} and A_{1g} Raman modes indicate MoS₂ is obtained on Au, h-BN and graphene (graphite), even though the contrast difference in the optical images are not strong enough to see if there is MoS₂ on the surface of h-BN or graphite. The MoS₂ layers 60 in these structures were confirmed to be monolayer by further studies.

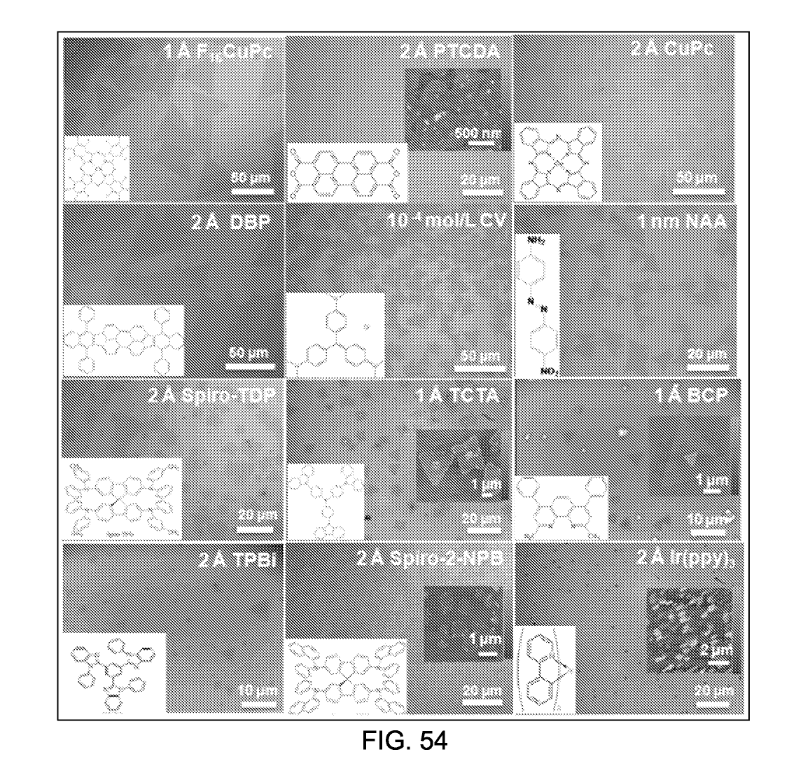

Additional embodiments use other organic molecules or inorganic particles to grow MoS₂ or other metal dichalcogenide. Twelve kinds of aromatic molecules, including F₁₆CuPc, copper phthalocyanine (CuPc), dibenzo{[f,f′]-4,4′,7,7′-tetraphenyl-diindeno[1,2,3-cd:1′,2′,3′-lm]perylene (DBP), crystal violet (CV), 3,4,9,10-perylene-tetracarboxylicacid-dianhydride (PTCDA), 4′-nitrobenzene-diazoaminoazobenzene (NAA), Tris(4-carbazoyl-9-ylphenyl) amine (TCTA), N,N′-Bis(3-methylphenyl)-N,N′-diphenyl-9,9-spirobifluorene-2,7-diamine (Spiro-TDP), bathocuproine (BCP), 1,3,5-tris(N-phenylbenzimiazole-2-yl)benzene (TPBi), 2,2′,7,7′-tetra(N-phenyl-1-naphthyl-amine)-9,9′-spirobifluorene (Spiro-2-NPS), and Iridium, tris(2-phenylpyidine) (Ir(ppy)₃), as well as four kinds of inorganic particles, including Al₂O₃ (aluminum oxide), HfO₂ (hafnium oxide), bare Si (with a very thin SiO₂ layer by natural oxidation), and Au, were used as seeds to grow MoS₂. FIG. 54 shows the typical optical images of the surface after MoS₂ growth for all of the organic seeds (AFM images are given for some of them, as some have small domains and are hard to see under the optical image). For most of the organic molecules, except Ir(ppy)₃ and Spiro-2-NPS, a continuous monolayer film or triangular flakes are observed on the substrates after the growth. However, for the inorganic seeds, either no MoS₂ growth was obtained (in the case of Al₂O₃, HfO₂ and bare Si) or only MoS₂ particles (in the case of Au, the results of which were similar to the results of the case without a seed).

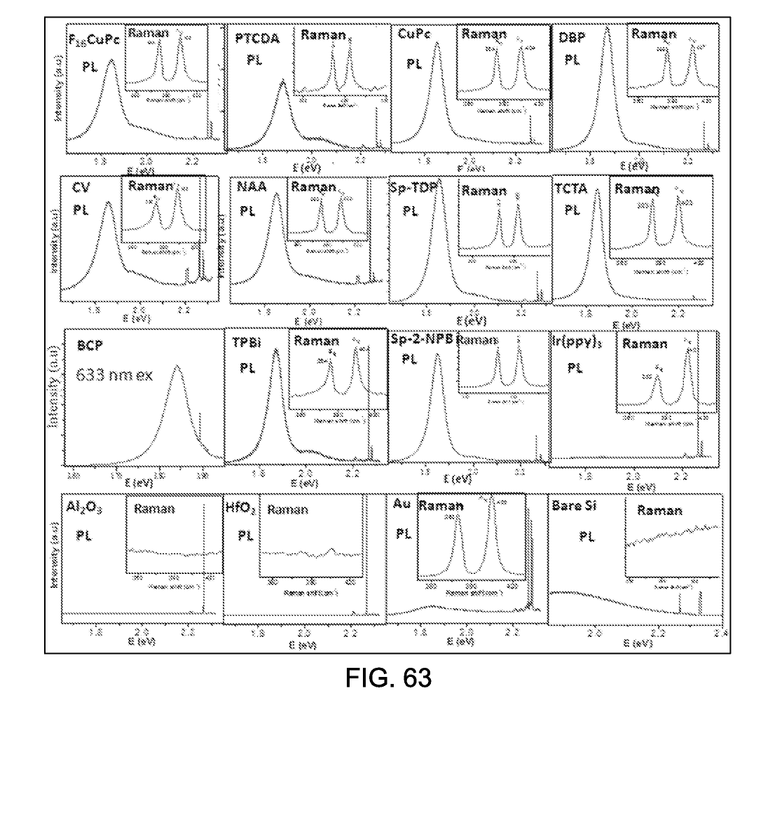

The PL and Raman results are shown in FIG. 63, which indicates that the growth yields monolayer MoS₂ for most of the aromatic seeds—except for Ir(ppy)₃, in which case multi-layer MoS₂ or particles were grown. The growth conditions (e.g., the amount of MoO₃ and S, temperature, the distance between the crucibles, gas flow rate, etc.) for these seeds, however, were not yet optimized; rather, the growth condition used for PTAS seed were used for all the cases here. Nevertheless, the results here can already provide a qualitative evaluation.

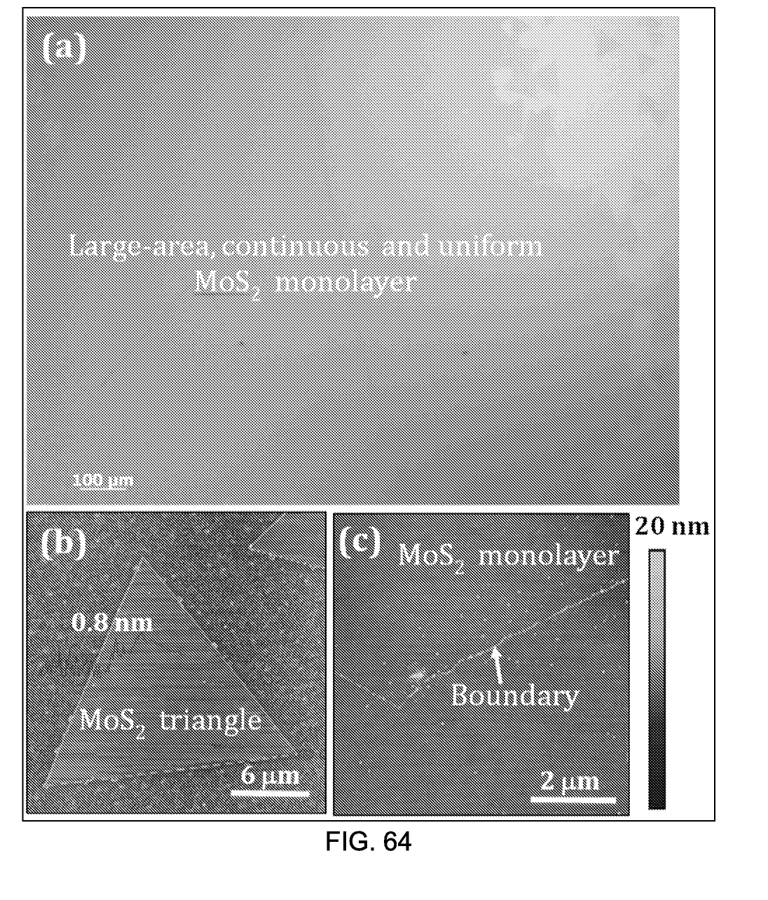

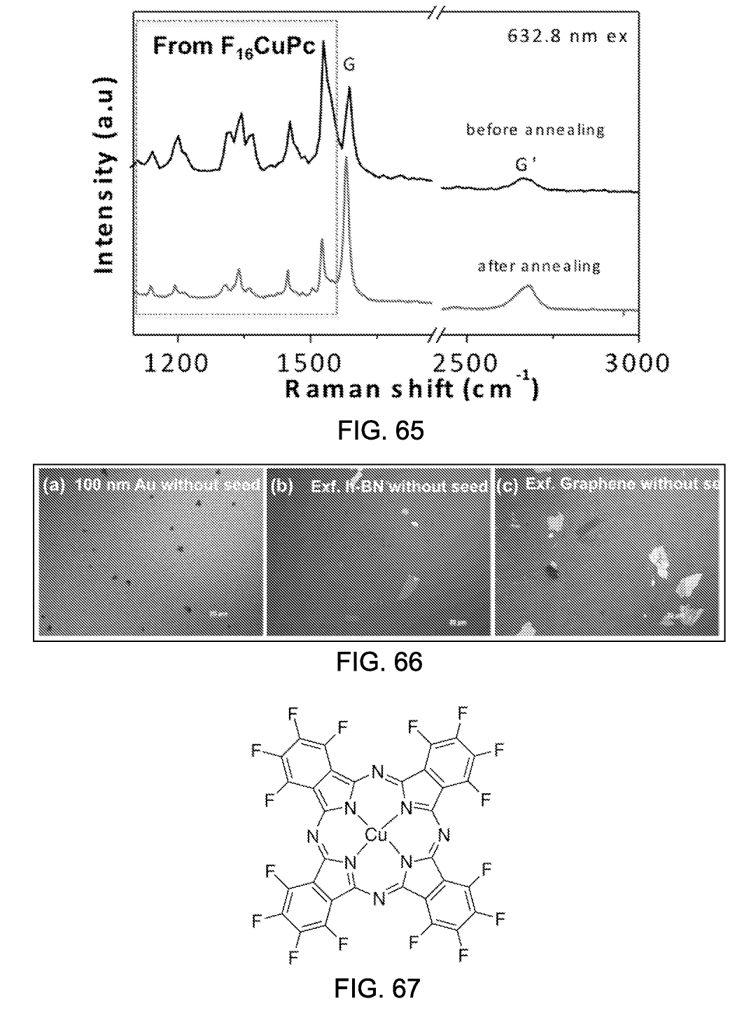

From these studies, we found that under the current growth condition, F₁₆CuPc (the molecular structure of which is shown in FIG. 67) is a seed comparable to PTAS, which can facilitate the growth of large-area, high-quality and uniform monolayer MoS₂ (or other metal dichalcogenide) growth (as shown in FIG. 64). The Raman spectra of 2 Å F₁₆CuPc on graphene before (top line) and after (bottom line) annealing at 650° C. are plotted in FIG. 65. The excitation wavelength is 632.8 nm. The G and G′-band of graphene are shown on the spectra. The peaks from 1100 to 1550 cm⁻¹ are assigned to the Raman modes of F₁₆CuPc. Here, we simulate the growth process of MoS₂ without introducing the reactants. The Raman spectra measurement shows that F₁₆CuPc remains on the surface after the process. It should be mentioned that due to the graphene-enhanced Raman scattering (GERS) effect, we can observe the Raman signals of such few F₁₆CuPc molecules on graphene, especially after the annealing.

Optical-microscope images are provided in FIG. 66 of MoS₂ growth (a) without using a seed on Au/SiO₂/Si, (b) without using a seed on exfoliated h-BN/SiO₂/Si, and (c) without using a seed on exfoliated graphene/SiO₂/Si. FIG. 66 shows that the MoS₂ growth behavior is more like the MoS₂ growth on the blank silicon, where there are only MoS₂ particles rather than the MoS₂ monolayer.

For other molecules under the current growth condition, the resulting MoS₂ flake sizes are of the following order: (CuPc, PTCDA, DBP, CV)>(NAA, Spiro-TDP, TCTA)>(BCP, TPBi, Spiro-2-NPS, Ir(ppy)₃). However, for the inorganic seeds, no monolayer MoS₂ formed via the growth processes. For 5 Å Au used as seed, there are only MoS₂ particles obtained by the island growth mechanism. Except for the aromatic structure of the seed, the sublimation temperature and the decomposition temperature are considered when selecting the composition for the seed, since the growth is carried out at a high temperature (650° C.). In Table 2, below, we summarized the features of the seeds as well as the growth results.

TABLE 2
Summary of the MoS₂ growth results using various seeds:

| | | Sublimation/ | | | |
|---|---|---|---|---|---|
| | | Decomposition | Growth results | | |
| | | temperature | Domain | | Overall |
| Types | Seed | (° C.) | size (mm) | Thickness | quality |
| Organic | PTAS | >600/high | ~60 | 1L | excellent |
| | F₁₆CuPc | >430 | ~60 | 1L | excellent |
| | CuPc | >430 | ~30 | 1L | good |
| | DBP | 350~450 | ~50 | 1L | good |
| | CV | ~205 | ~20 | 1L | good |
| | | (decompose) | | | |
| | PTCDA | >450 | continuous | 1L | good |
| | | | film | | |
| | NAA | ~200 | ~15 | 1L | good |
| | | (decompose) | | | |
| | Spiro-TPD | >280 | ~10 | 1L | fair |
| | TCTA | >410 | ~10 | 1L & ML | fair |
| | BCP | >240/300 | ~5 | 1L & ML | fair |
| | TPBI | >350 | ~5 | 1L & ML | poor |
| | Spiro-2- | >390 | ~1 | 1L & ML | poor |
| | NPB | | | | |
| | Ir(ppy)₃ | >300 | N/A | ML | bad |
| In- | Al₂O₃ | High | N/A | Almost | bad |
| organic | | | | nothing | |
| | HfO₂ | High | N/A | Almost | bad |
| | | | | nothing | |
| | 5 Å Au | High | N/A | Particles | bad |
| | Bare Si | High | N/A | Almost | bad |
| | | | | nothing | |

In the above table, the sublimation temperature is determined by thermogravimetric analysis (TGA); and for the thickness indications, 1L indicates growth of a monolayer, while ML indicates multilayer growth.

Among the organic seeds, F₁₆CuPc has the highest stability at high temperature, which results in the best growth result. In contrast, some of the other seeds, such as BCP, TPBi, Spiro-2-NPS and Ir(ppy)₃, sublimate at relatively low temperatures and are very easy to decompose; and we believe that this seed decomposition is responsible for the poor growth result of the small domains and the lack of a continuous film. Therefore, a good seed for MoS₂ growth can be an organic molecule that has good wettability with MoS₂ and is stable enough to remain on the substrate under the growth temperature and other growth conditions.

In a particular exemplification for preparing MoS₂/Au hybrid structures, a 100-nm Au layer was first deposited on a SiO₂/Si substrate by vacuum thermal evaporation. For MoS₂/h-BN and MoS₂/graphene (graphite) growth, mechanically exfoliated h-BN and graphene (graphite) were first transferred to the SiO₂/Si substrate. Then, a 1 Å think layer of F₁₆CuPc was deposited on these substrates by thermal evaporation. Since the F₁₆CuPc is hydrophobic and planar, it can stably and uniformly adhere to the Au, h-BN and graphene substrates, as was confirmed by the Raman spectral characterization. The Raman signals of F₁₆CuPc on graphene can still be observed after annealing at 650° C. (the growth temperature) for one hour (see FIG. 65). The substrate with the F₁₆CuPc seed was used to grow MoS₂ monolayers routinely and allowed us to prepare the MoS₂/Au, MoS₂/h-BN and MoS₂/graphene (graphite) hybrid structures directly. When there was no F₁₆CuPc seed on these substrates, no MoS₂ monolayers were obtained on the substrates (see FIG. 66).

Identifying the new seed molecules greatly facilitates the fabrication of hybrid structures involving MoS₂. Hybrid structures between a transition-metal-dichalcogenide monolayer, a graphene-like 2D material and some functional materials, such as graphene, h-BN and metals, have very attractive properties for applications in high-performance electronic and optoelectronic devices. PTAS works excellently as a seed for promoting MoS₂ growth on hydrophilic substrates since PTAS is a salt and is typically applied with aqueous solution. Meanwhile, F₁₆CuPc is highly advantageous for use as a seed for promoting MoS₂ growth on hydrophobic surfaces.

In describing embodiments of the invention, specific terminology is used for the sake of clarity. For the purpose of description, specific terms are intended to at least include technical and functional equivalents that operate in a similar manner to accomplish a similar result. Additionally, in some instances where a particular embodiment of the invention includes a plurality of system elements or method steps, those elements or steps may be replaced with a single element or step; likewise, a single element or step may be replaced with a plurality of elements or steps that serve the same purpose. Further, where parameters for various properties or other values are specified herein for embodiments of the invention, those parameters or values can be adjusted up or down by 1/100^{th}, 1/50^{th}, 1/20^{th}, 1/10^{th}, ⅕^{th}, ⅓^{rd}, ½, ⅔^{rd}, ¾^{th}, ⅘^{th}, 19/20^{th}, 49/50^{th}, 99/100^{th}, etc. (or up by a factor of 1, 2, 3, 4, 5, 6, 8, 10, 20, 50, 100, etc.), or by rounded-off approximations thereof, unless otherwise specified. Moreover, while this invention has been shown and described with references to particular embodiments thereof, those skilled in the art will understand that various substitutions and alterations in form and details may be made therein without departing from the scope of the invention. Further still, other aspects, functions and advantages are also within the scope of the invention; and all embodiments of the invention need not necessarily achieve all of the advantages or possess all of the characteristics described above. Additionally, steps, elements and features discussed herein in connection with one embodiment can likewise be used in conjunction with other embodiments. The contents of references, including reference texts, journal articles, patents, patent applications, etc., cited throughout the text are hereby incorporated by reference in their entirety; and appropriate components, steps, and characterizations from these references may or may not be included in embodiments of this invention. Still further, the components and steps identified in the Background section are integral to this disclosure and can be used in conjunction with or substituted for components and steps described elsewhere in the disclosure within the scope of the invention. In method claims, where stages are recited in a particular order—with or without sequenced prefacing characters added for ease of reference—the stages are not to be interpreted as being temporally limited to the order in which they are recited unless otherwise specified or implied by the terms and phrasing.

What is claimed is:

1. A method for producing a metal dichalcogenide layer on a transfer substrate, comprising:
seeding F₁₆CuPc molecules on a surface of a growth substrate;
growing a layer of a metal dichalcogenide via chemical vapor deposition on the growth substrate surface seeded with F₁₆CuPc molecules; and
contacting the F₁₆CuPc-molecule and metal-dichalcogenide coated growth substrate with a composition that releases the metal dichalcogenide from the growth substrate.

2. The method of claim 1, further comprising adhering a transfer medium to the metal dichalcogenide layer before the metal dichalcogenide layer is released from the growth substrate.

3. The method of claim 2, where the transfer medium includes a polymer selected from polydimethylsiloxane and poly(methyl methacrylate) (PMMA).

4. The method of claim 1, further comprising, after the metal dichalcogenide layer is released from the growth substrate, applying the metal dichalcogenide layer to a target substrate.

5. The method of claim 4, wherein the target substrate comprises a composition selected from quartz, sapphire and silica.

6. The method of claim 1, wherein the metal dichalcogenide has a composition represented by the formula, MX₂, where M includes a metal selected from molybdenum (Mo) and tungsten (W), and where X is a chalcogen selected from sulfur (S), selenium (Se) and tellurium (Te).

7. The method of claim 1, wherein the F₁₆CuPc molecules are seeded by thermal evaporation.

8. The method of claim 7, wherein the seed is uniformly distributed on the substrate.

9. The method of claim 1, wherein the metal dichalcogenide layer is a monolayer.

10. The method of claim 1, wherein the composition that releases the metal dichalcogenide includes an inorganic base solution.

11. The method of claim 10, wherein the inorganic base in the solution is selected from at least one of potassium hydroxide and sodium hydroxide.

12. The method of claim 1, wherein the growth substrate comprises SiO₂/Si.

13. The method of claim 1, wherein the growth substrate has a hydrophobic surface on which the F₁₆CuPc molecules are seeded.

14. The method of claim 1, wherein the growth substrate comprises at least one of gold, boron nitride and graphene.

15. A metal dichalcogenide layer on a substrate, comprising:
a growth substrate;
Fe₁₆CuPc seed molecules on the growth substrate; and
a metal dichalcogenide layer on the Fe₁₆CuPc seed molecules.

16. The metal dichalcogenide layer on a substrate of claim 15, wherein the growth substrate comprises at least one of gold, boron nitride and graphene.

17. The metal dichalcogenide layer on a substrate of claim 15, further comprising a transfer medium on the metal dichalcogenide layer, wherein the transfer medium includes a polymer selected from polydimethylsiloxane and poly(methyl methacrylate) (PMMA).

18. The metal dichalcogenide layer on a substrate of claim 15, wherein the metal dichalcogenide has a composition represented by the formula, MX₂, where M includes a metal selected from molybdenum (Mo) and tungsten (W), and where X is a chalcogen selected from sulfur (S), selenium (Se) and tellurium (Te).

19. The metal dichalcogenide layer on a substrate of claim 15, wherein the metal dichalcogenide layer is a monolayer.

20. The metal dichalcogenide layer on a substrate of claim 15, wherein the growth substrate has a hydrophobic surface to which the Fe₁₆CuPc seed molecules are adhered.
